(19) United States
(12) Patent Application Publication
(10) Pub. No.: US 2018/0358305 A1
(43) Pub. Date: Dec. 13, 2018

(54) WAFER LEVEL PACKAGE AND MANUFACTURING METHOD THEREOF

(71) Applicant: WISOL CO., LTD., Osan-si (KR)

(72) Inventors: Jung Hoon HAN, Osan-si (KR); Eun Tae PARK, Osan-si (KR); Jin Ho HA, Osan-si (KR); Jun Woo YONG, Osan-si (KR)

(21) Appl. No.: 15/992,376

(22) Filed: May 30, 2018

(30) Foreign Application Priority Data
Jun. 8, 2017 (KR) 10-2017-0071856

(51) Int. Cl. H01L 23/00

(52) U.S. Cl. CPC H01L 23/562; H01L 23/564; H01L 24/09; H01L 24/30; H01L 2924/0105; H01L 2224/83051; H01L 2924/01029; H01L 2924/01079; H01L 24/83

(57) ABSTRACT

A wafer level package includes: a substrate having a circuit pattern unit, a pad spaced apart from the circuit pattern unit, a bonding pad disposed on a side of the pad, and a first protection dam; and a printed circuit board having a connection pad and a second protection dam, where the substrate and the printed circuit board are attached through the bonding and connection pads and the first and second protection dams.

A method of manufacturing a wafer level package includes: forming a circuit pattern unit on a substrate; disposing a pad spaced apart from the circuit pattern unit; forming a secondary film on a side of the pad; forming a protection film, excluding some of the pads where the secondary film is formed; disposing a bonding pad and a protection dam on a side of the pad; attaching the manufactured substrate and printed circuit board to each other.

### CROSS REFERENCE TO RELATED APPLICATION

The present application claims priority to Korean Patent Application No. 10-2017-0071856, filed in the Korean Intellectual Property Office on Jun. 8, 2017, the entire content of which is incorporated herein by reference.

### BACKGROUND OF THE INVENTION

### 1. Field of the Invention

The present invention relates to a wafer level package and a manufacturing method thereof.

### 2. Description of Related Art

An surface acoustic wave device is configured to install an input electrode and an output electrode of a thin metal film at both ends on the surface of a piezoelectric medium to input a high frequency electrical signal, convert the input signal into a surface acoustic wave, detect propagation characteristics through the output electrode and restore the electrical signal.

Meanwhile, a manufacturing method using a wafer level package (WLP) is frequently used in manufacturing a semiconductor device, in which a product is simply manufactured by cutting chips after a package process and a test are progressed at a time in a wafer state, and wafer level packages for improving productivity and reducing manufacturing cost are attempted from various angles. In addition, modifications of the wafer level package is diversely attempted to solve the problem of product defect of the wafer level package.

In the conventional technique, a semiconductor package having a protection dam disposed along the edge of an electrode pattern of a semiconductor package is disclosed.

However, such a conventional technique has a problem in that manufacturing throughput is lowered and manufacturing cost is increased due to the problem of a structure, such as a protection dam or the like, of being collapsed when a molding unit is formed on the top of an element to manufacture a module after manufacturing the element.

### SUMMARY OF THE INVENTION

An object of the present invention to provide a wafer level package of improved reliability and a manufacturing method thereof.

A wafer level package according to the present invention includes a substrate having a circuit pattern unit, a pad formed to be spaced apart from the circuit pattern unit, a bonding pad disposed on a side of the pad, and a first protection dam; and a printed circuit board having a connection pad and a second protection dam, and the substrate and the printed circuit board may be attached through the bonding pad, the connection pad, the first protection dam and the second protection dam.

In addition, the bonding pad may be configured of conductive materials of single layer or multiple layers.

In addition, the first protection dam may have conductive materials and a structure the same as those of the bonding pad.

In addition, the bonding pad and the connection pad, and the first protection dam and the second protection dam may be attached to configure a Cu—Sn—Cu or Au—Sn—Au structure overall.

In addition, when the bonding pad and the connection pad, and the first protection dam and the second protection dam are attached to configure a Cu—Sn—Cu structure overall, the connection pad and the second protection dam may be configured as a Cu single layer structure if the bonding pad and the first protection dam are a Cu—Sn stack structure, and the connection pad and the second protection dam may be configured as a Sn—Cu stack structure if the bonding pad and the first protection dam are a Cu single layer structure.

In addition, when the bonding pad and the connection pad, and the first protection dam and the second protection dam are attached to configure an Au—Sn—Au structure overall, the connection pad and the second protection dam may be configured as an Au single layer structure if the bonding pad and the first protection dam are an Au—Sn stack structure, and the connection pad and the second protection dam may be configured as an Sn—Au stack structure if the bonding pad and the first protection dam are an Au single layer structure.

In addition, the circuit pattern unit may be an IDT electrode unit.

A method of manufacturing a wafer level package according to the present invention includes the steps of forming a circuit pattern unit on a substrate; disposing a pad to be spaced apart from the circuit pattern unit; forming a secondary film on a side of the pad; forming a protection film, excluding some of the pads on which the secondary film is formed; disposing a bonding pad and a protection dam on a side of the pad; and attaching the manufactured substrate and printed circuit board to each other, and the substrate may be simply manufactured compared with a plating method.

In addition, the bonding pad may be configured of conductive materials of single layer or multiple layers.

In addition, the first protection dam may have conductive materials and a structure the same as those of the bonding pad.

In addition, at the step of disposing a bonding pad and a protection dam on a side of the pad, the conductive materials configuring the bonding pad 108 and the first protection dam 106 may be simultaneously formed through evaporation.

### BRIEF DESCRIPTION OF THE DRAWINGS

FIG. 1 is a cross-sectional view showing a conventional wafer level package.

FIG. 2 is a cross-sectional view showing a wafer level package according to an embodiment of the present invention.

FIGS. 3A to 3H are views showing a general process of manufacturing a substrate configuring a conventional wafer level package.

FIGS. 4A to 4E are views showing a process of manufacturing a wafer level package according to an embodiment of the present invention.

FIG. 5 is a cross-sectional view showing a substrate configuring a wafer level package according to an embodiment of the present invention.

FIG. 6 is a cross-sectional view showing a module in which a wafer level package according to an embodiment of the present invention is installed in a module printed circuit board.

### DETAILED DESCRIPTION OF THE PREFERRED EMBODIMENT

Details of the objects and technical configuration of the present invention described above and operational effects according thereto will be further clearly understood by the detailed description hereinafter.

In the description of the present invention, if a substrate, a layer (film), a region, a pattern or a structure is referred to as being formed or disposed “up/on” or “down/under” another substrate, layer (film), region, pad or pattern, it can be “directly” formed or disposed or “indirectly” formed or disposed with the intervention of other layers. Classification of “up/on” or “down/under” of each layer is defined on the basis of drawings.

Singular expressions used hereinafter include plural expressions, unless the context clearly indicates otherwise. The terms such as “include”, “have” and the like are to specify existence of features, numbers, steps, operations, elements, components or a combination of these stated in the specification, and it may be interpreted as addition of one or more of other features, numbers, steps, operations, elements, components or a combination of these.

Hereinafter, the present invention will be described in detail with reference to the accompanying drawings.

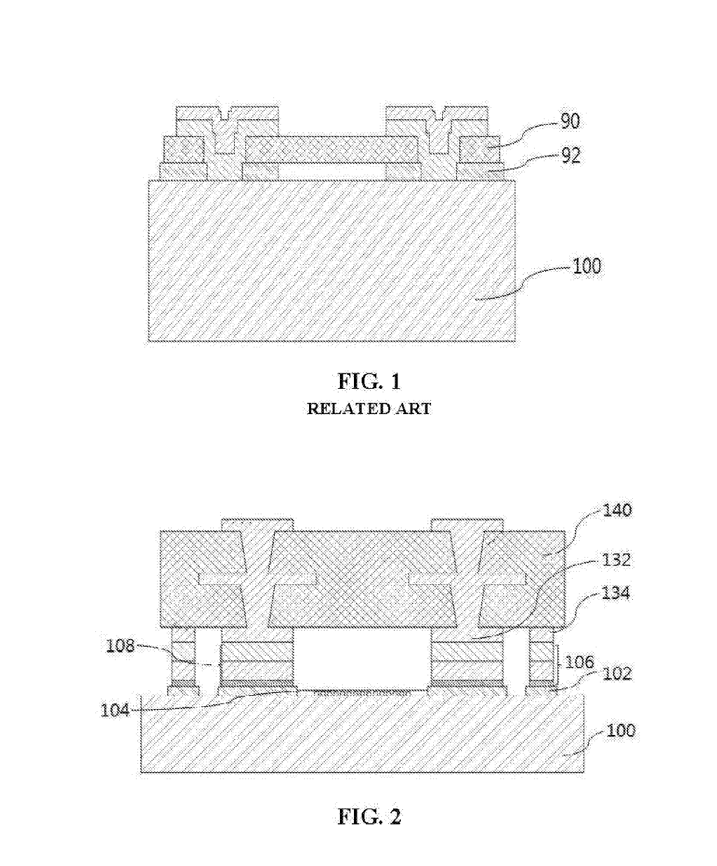

FIG. 1 is a cross-sectional view showing a conventional wafer level package.

A conventional wafer level package may include a wall layer 92, a roof layer 90 and a contact layer (not shown) on a substrate 100.

Since such a conventional wafer level package needs many processes such as a seed forming process for plating the wall layer 92 and the roof layer 90, a plating process, an etching process and the like, it becomes a factor of increasing manufacturing cost.

In addition, when transfer molding is conducted to a wafer level package attached to a module printed circuit board for modularization, the roof layer 90 may collapse and contact with the substrate 100, and thus the wall layer 92 may contact with the roof layer 92. This problem will cause decrease of reliability.

FIG. 2 is a cross-sectional view showing a wafer level package according to an embodiment of the present invention.

As shown in FIG. 2, although a wafer level package according to an embodiment of the present invention may be a wafer level package of a form attached to a printed circuit board 140, it is not limited thereto.

A wafer level package according to an embodiment of the present invention may include a printed circuit board 140, a substrate 100 and a circuit pattern unit 104.

Through a bonding pad 108 and a first protection dam 106, instead of the roof layer 90 and the wall layer 92, the wafer level package according to an embodiment of the present invention may prevent the problem of the roof layer 90 collapsing and contacting with the substrate when transfer molding is performed.

Although the circuit pattern unit 104 is described using an IDT electrode unit as an example, it is not limited thereto.

The IDT electrode unit may be an electrode using a surface acoustic wave generated and propagated by a voltage applied to an Inter Digital Transducer (IDT).

Although the substrate 100 may be a wafer and may be a piezoelectric single crystal such as LiNbO3, LiTaO3, SiO2, Li2B4O7 or the like, a piezoelectric thin film such as SnO, AlN or the like, a PZT-based ceramic, or a LT(LiTaO3) substrate, it is not limited thereto.

The substrate 100 may include a pad 102, a bonding pad 108 and a first protection dam 106.

The pad 102 may be disposed on the substrate 100 to be spaced apart from the circuit pattern 104.

Although the pad 102 may be configured as a single layer or a plurality of layers, it is not limited thereto.

The pad 102 may be configured of conductive materials, and although the pad 102 may be configured of materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

The bonding pad 108 and the first protection dam 106 are disposed on a side of the pad 102.

The bonding pad 108 may be configured of conductive materials, and although the bonding pad 108 may be implemented using materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

Although the bonding pad 108 may be implemented using conductive materials of single layer or multiple layers, it is not limited thereto.

The first protection dam 106 may be disposed on a side of the pad 102 to surround the edge of the substrate 100.

The first protection dam 106 may be configured of conductive materials, and although the first protection dam 106 may be implemented using materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

Although the first protection dam 106 may be configured of conductive materials of single layer or multiple layers, it is not limited thereto.

Although the first protection dam 106 and the bonding pad 108 may be configured of the same material, it is not limited thereto.

Since the substrate 100 on which the bonding pad 108 and the first protection dam 106 are disposed is metal-bonded to the printed circuit board 140, reliability of the wafer level package can be improved as they are hermetically sealed.

The printed circuit board 140 may include a connection pad 132 and a second protection dam 134.

The connection pad 132 and the second protection dam 134 are disposed at positions corresponding to the bonding pad 108 and the first protection dam 106. The second protection dam 134 is disposed along the edge of the printed circuit board 140.

The connection pad 132 may be configured of conductive materials, and although the connection pad 132 may be implemented using materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

The second protection dam 134 may be configured of conductive materials, and although the second protection dam 134 may be implemented using materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

Although the second protection dam 134 and the connection pad 132 may be implemented using the same material, it is not limited thereto.

The substrate 100 and the printed circuit board 140 may be TLP-bonded, and when the TLP bonding is conducted, the bonding pad 108 and the first protection dam 106 disposed on the substrate 100 are attached to the connection pad 132 and the second protection dam 134 disposed on the printed circuit board 140.

The bonding pad 108 and the connection pad 132, and the first protection dam 106 and the second protection dam 134 are attached to have a structure of Cu—Sn—Cu or Au—Sn—Au overall.

When the bonding pad 108 and the connection pad 132, and the first protection dam 106 and the second protection dam 134 are attached to have a Cu—Sn—Cu structure overall, the connection pad 132 and the second protection dam 134 may be configured as a Cu single layer structure if the bonding pad 108 and the first protection dam 106 are a Cu—Sn stack structure, and the connection pad 132 and the second protection dam 134 may be configured as a Sn—Cu stack structure if the bonding pad 108 and the first protection dam 106 are a Cu single layer structure.

When the bonding pad 108 and the connection pad 132, and the first protection dam 106 and the second protection dam 134 are attached to have an Au—Sn—Au structure overall, the connection pad 132 and the second protection dam 134 may be configured as an Au single layer structure if the bonding pad 108 and the first protection dam 106 are an Au—Sn stack structure, and the connection pad 132 and the second protection dam 134 may be configured as an Sn—Au stack structure if the bonding pad 108 and the first protection dam 106 are an Au single layer structure.

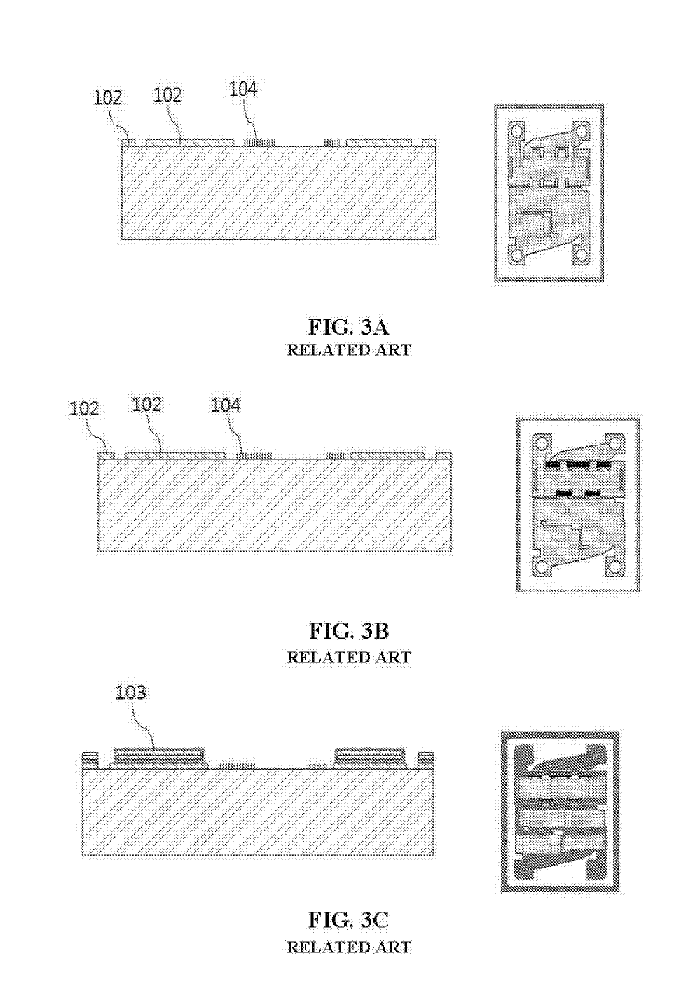

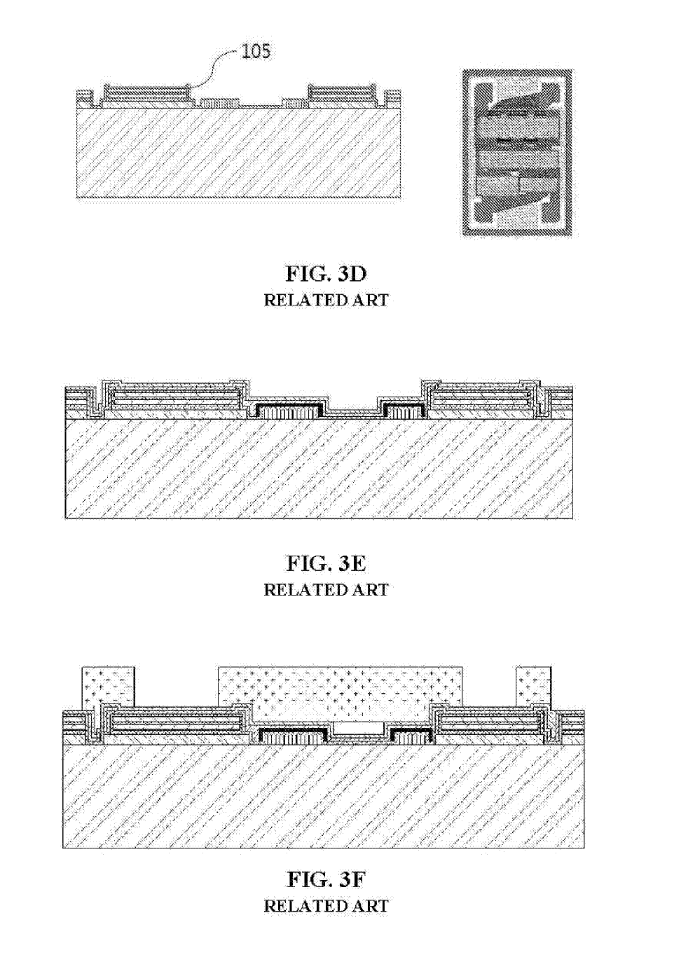

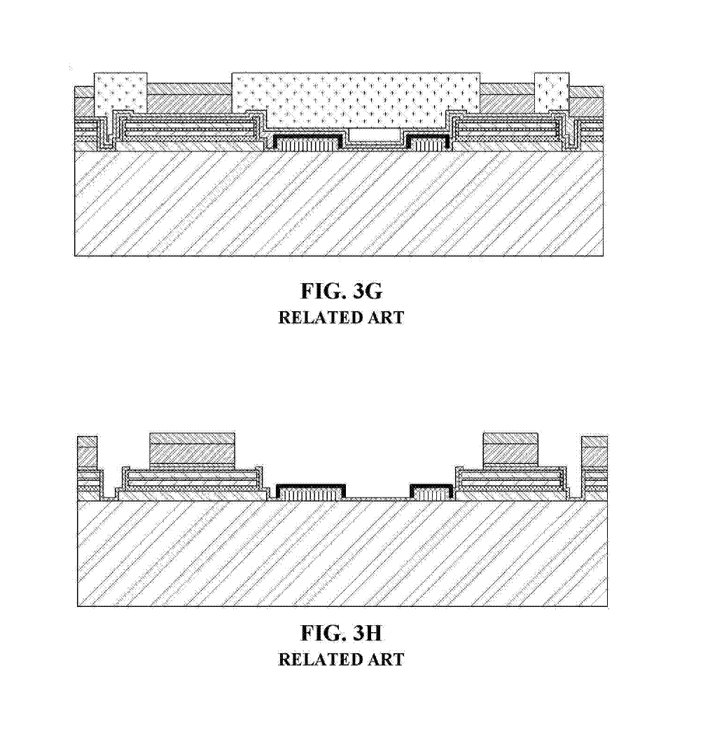

FIGS. 3A to 3H are views showing a general process of manufacturing a substrate configuring a conventional wafer level package.

As shown in FIG. 3A, a circuit pattern unit 104 is formed on the substrate 100. The circuit pattern unit 104 may be a plurality of IDT electrode units formed at the central area of the substrate 100 in the form of a comb-shaped metal plate. The IDT electrode unit may be implemented without restriction if conductive materials are used, and although the IDT electrode unit may be formed of materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

A conductive material is deposited on the front surface of the substrate 100. Then, the IDT electrode unit is formed by etching all the conductive material except the metal formed in the central area of the substrate through a photolithography process (coating, exposure and development) using photoresist. A wet etching method using boron chloride, chorine gas or the like may be selected as a metal etching method, and then, unnecessary photoresist patterns are removed through a strip process.

Subsequently, a plurality of pads 102 is formed on the substrate 100 to be spaced apart from the circuit pattern unit 104.

As shown in FIG. 3B, a bridge is formed to connect wires.

Since surface mount technology (SMT) is progressed by forming a via in the pad 102, the position of the pad should be fixed at a specific position.

As shown in FIG. 3C, a secondary film 103 may be formed on the pad 102 and the protection dam 106.

The secondary film 103 may be configured of conductive materials, and although the secondary film 103 may be implemented using copper (Cu), titanium (Ti), aluminum (Al), gold (Au), tin (Sn) and the like, it is not limited thereto.

The secondary film 103 may be implemented as multiple layers using various conductive materials, and it may be, for example, Ti/Al/Ti, Ti/Al/Ti/Au, Ti/Al/Ti/Au/Cu, Ti/Al/Ti/Au/Cu/Sn, Ti/Al/Ti/Au/Ti/Cu/Sn or the like.

Alternatively, although Ti/Cu or Ti/Cu/Sn may be progressed as a tertiary film after etching Ti in a stacked Ti/Al/Ti/Au/Ti, it is not limited thereto.

Although the secondary film 103 may be implemented using electroplating, electroless plating, sputtering, evaporating, 3D printing or the like, it is not limited thereto.

As shown in FIG. 3D, a protection film 105 is formed, leaving only some of the pads 102.

Although the protection film 105 may be configured as SiOx and SiN, it is not limited thereto. For example, it may be implemented as SiOx-SiN-SiOx, SiN, SiOx-SiN or the like.

As shown in FIG. 3E, a seed layer is formed on the top of the secondary film 103 and the protection film 105.

The seed layer may be formed of conductive materials, and although the seed layer may be implemented using copper (Cu), titanium (Ti), gold (Au), chrome (Cr), nickel (Ni) and the like, it is not limited thereto.

The seed layer may be implemented in a plurality of layers of various metallic materials and may be, for example, Ti/Cu or Ti/Au, Ti/Cr, Ti/Ni.

As shown in FIG. 3F, a photoresist pattern for plating is formed on a side of the substrate on which the seed layer is formed.

As shown in FIG. 3G, plating is conducted on the area where the photoresist pattern is not formed.

Although one or more metallic materials of good conductivity, e.g., copper (Cu), silver (Ag), palladium (Pd), aluminum (Al), nickel (Ni), titanium (Ti), gold (Au), platinum (Pt), tin (Sn) and the like, may be plated when the plating conducted, it is not limited thereto.

As shown in FIG. 3H, after removing the unnecessary photoresist patterns through a strip process, the seed layer is etched.

The substrate 100 completed according to the manufacturing process described above may be attached to the printed circuit board 140 to configure a wafer level package.

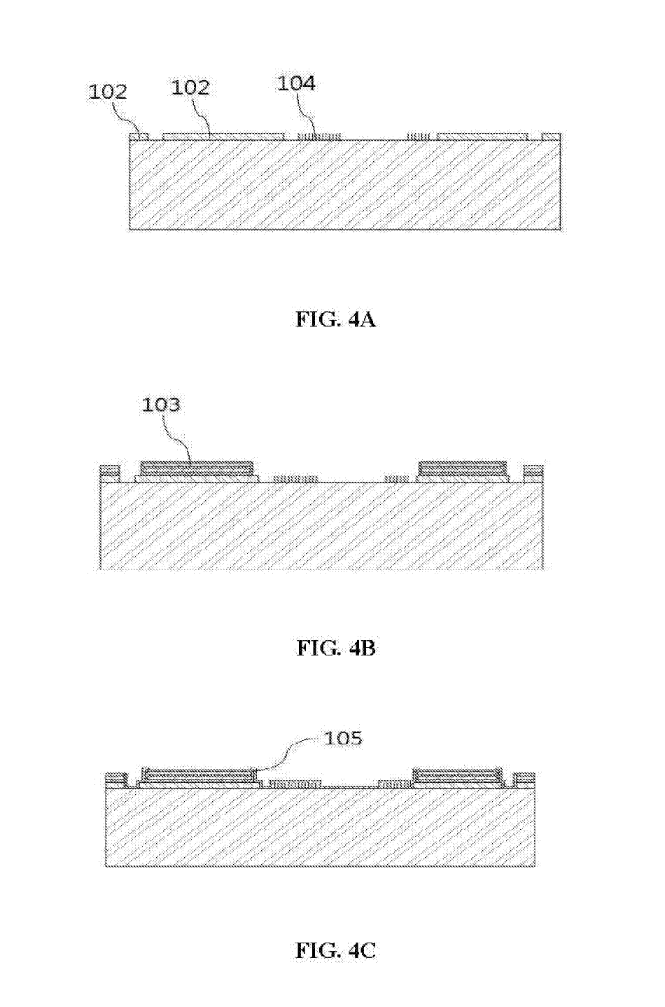

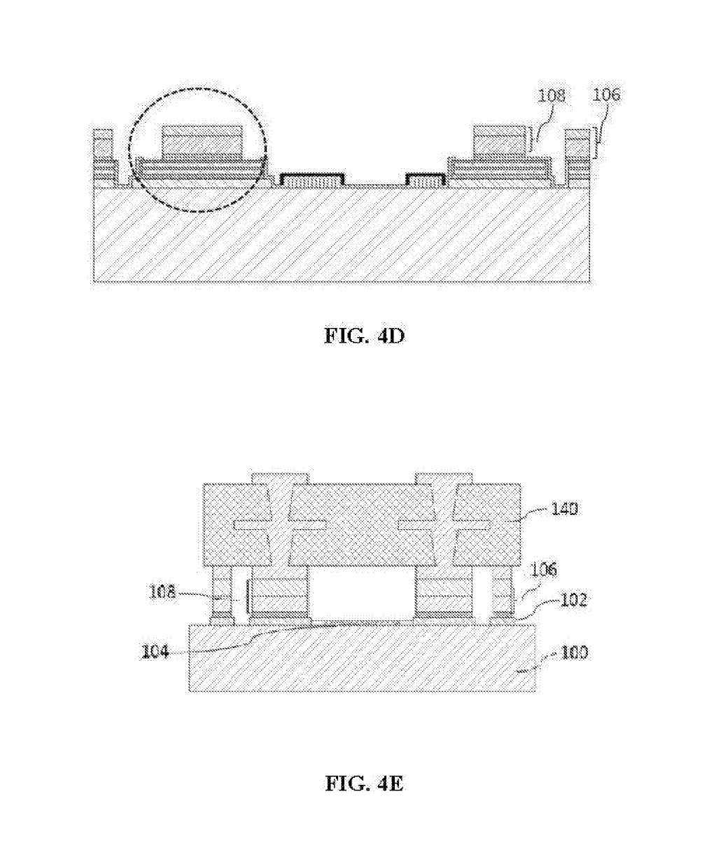

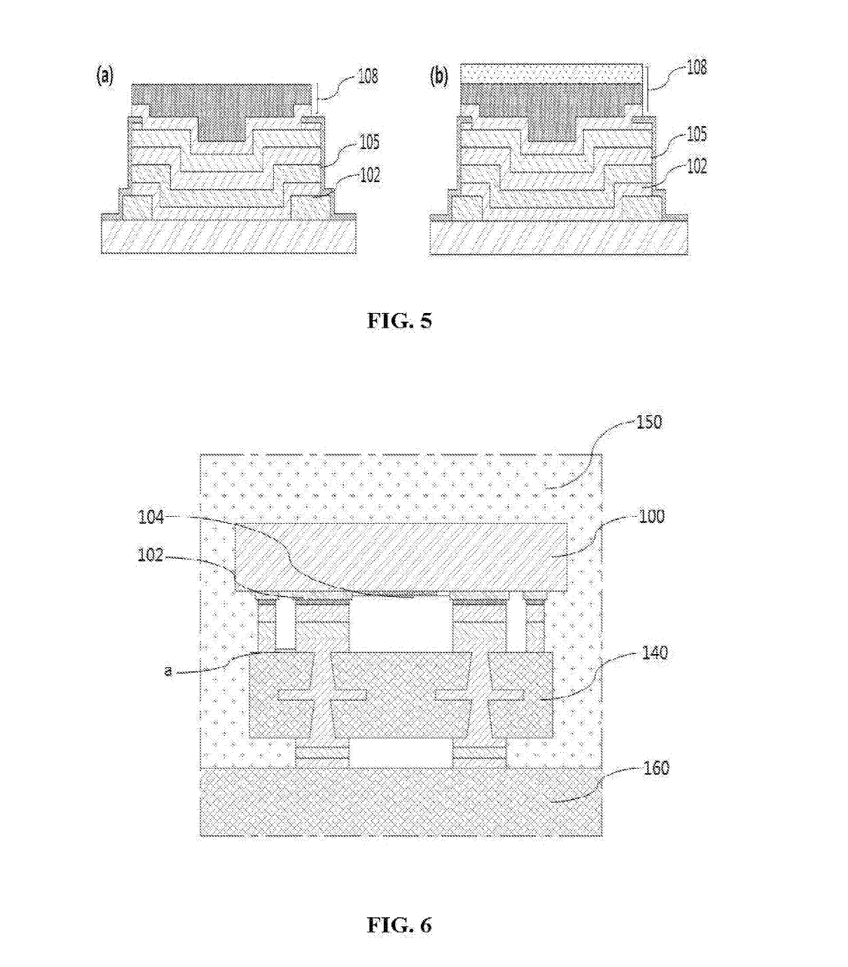

FIGS. 4A to 4E are views showing the process of manufacturing a substrate configuring a wafer level package according to the present invention.

As shown in FIG. 4A, a circuit pattern unit 104 is disposed on the substrate 100. Although the circuit pattern unit 104 is described using an IDT electrode unit as an example, it is not limited thereto.

The circuit pattern unit 104 may form a plurality of IDT electrode units at the central area of the substrate in the form of a comb-shaped metal plate. The IDT electrode unit may be implemented without restriction if conductive materials are used, and although the IDT electrode unit may be formed of materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

A conductive material is deposited on the front surface of the substrate 100. Then, the IDT electrode unit is formed by etching all the conductive material except the metal formed in the central area of the substrate through a photolithography process (coating, exposure and development) using photoresist. A wet etching method using boron chloride, chorine gas or the like may be selected as a metal etching method, and then, unnecessary photoresist patterns are removed through a strip process.

Subsequently, a plurality of pads 102 is disposed on the top of the substrate 100 to be spaced apart from the circuit pattern unit 104.

As shown in FIG. 4B, a secondary film 103 may be formed on a side of the pad 102 disposed on the substrate 100.

The secondary film 103 may be implemented using conductive materials, and although the secondary film 103 may be implemented using copper (Cu), titanium (Ti), aluminum (Al), gold (Au), tin (Sn) and the like, it is not limited thereto.

The secondary film 103 may be formed in multiple layers using various conductive materials, and it may be, for example, Ti—Cu, Ti/Al/Ti, Ti—Al—Ti—Cu, Ti/Al/Ti/Au, Ti/Al/Ti/Au/Cu, Ti/Al/Ti/Au/Cu/Sn, Ti/Al/Ti/Au/Ti/Cu/Sn or the like.

After the manufacturing is progressed as far as the secondary film 103, a protection film 105 may be formed.

Alternatively, Ti/Cu, Ti/Cu/Sn, Ti/Au or Ti/Au/Sn may be progressed as a tertiary film after etching Ti in the secondary film 103 of stacked Ti/Al/Ti/Au/Ti, and a protection layer 105 may be formed thereafter.

The secondary film 103 may be implemented using electroplating, electroless plating, sputtering, evaporating, 3D printing or the like.

As shown in FIG. 4C, a protection film 105 is formed, excluding only some of the pads 102.

The protection film 105 may electrically insulate the pads 102 and, at the same time, performs a function of exposing some of the pads 102. Although the protection film 105 may be configured of dielectrics such as SiOx, SiN and the like, it is not limited thereto. For example, it may be implemented as SiOx-SiN-SiOx, SiN, SiOx-SiN or the like.

As shown in FIG. 4D, the bonding pad 108 and the first protection dam 106 are disposed on a side of the pad 102.

The bonding pad 108 may be configured of conductive materials, and although the bonding pad 108 may be implemented using materials having excellent electrical characteristics, such as copper (Cu), silver (Ag), palladium (Pd), aluminum (Al), nickel (Ni), titanium (Ti), gold (Au), platinum (Pt), tin (Sn) and the like, it is not limited thereto.

The first protection dam 106 may be configured of conductive materials, and although the first protection dam 106 may be implemented using materials having excellent electrical characteristics, such as copper (Cu), silver (Ag), palladium (Pd), aluminum (Al), nickel (Ni), titanium (Ti), gold (Au), platinum (Pt) and the like, it is not limited thereto.

Although the first protection dam 106 may be implemented using materials the same as those the bonding pad 108, it is not limited thereto.

The conductive materials configuring the bonding pad 108 and the first protection dam 106 may be simultaneously formed through evaporation.

Cu—Sn may be sequentially stacked to implement the bonding pad 108 and the first protection dam 106.

Since the tin (Sn) layer needs to exist in either the printed circuit board 140 or the substrate 100, when the printed circuit board 140 and the substrate 100 are attached using the tin (Sn) of the printed circuit board 140, the tin (Sn) does not need to be plated on the substrate.

As another example, when the printed circuit board 140 and the substrate 100 are attached using Au—Sn, Au—Sn may be sequentially stacked, instead of Cu—Sn.

In the same manner as described above, since the tin (Sn) layer needs to exist in either the printed circuit board 140 or the substrate 100, when the printed circuit board 140 and the substrate 100 are attached using the tin (Sn) of the printed circuit board 140, the tin (Sn) does not need to be plated on the substrate 100.

As shown in FIG. 4E, the substrate 100 completed according to FIG. 4(a) to 4(d) may be attached to the printed circuit board 140 to complete a wafer level package.

As described above with reference to FIGS. 3A to 3H, a general process of manufacturing a substrate configuring a conventional wafer level package needs the processes such as forming a seed layer in a plating method, forming a photoresist pattern, plating, and etching a seed layer after a strip process. However, as described above with reference to FIGS. 4A to 4E, since the process of manufacturing a substrate configuring a wafer level package according to an embodiment of the present invention does not need the processes described above, the manufacturing process may be simplified.

It may be confirmed that the processes for manufacturing a substrate are remarkably simplified, compared with the conventional method.

FIG. 5 is enlarged views of the bonding pad 108 which is disposed on the substrate 100 and marked with a circle in FIG. 4D.

When the bonding pad 108 disposed on the substrate 100 and the connection pad 132 of the printed circuit board 140 are attached, it may include a Cu—Sn—Cu structure or an Au—Sn—Au structure overall.

As shown in (a) of FIG. 5, if the bonding pad 108 is a single layer structure configured as Cu, the connection pad 132 of the printed circuit board 140 may be a stack structure configured as Cu—Sn from the bottom, and as shown in (b) of FIG. 5, if the bonding pad 108 is a stack structure configured as Cu—Sn from the bottom, the connection pad 132 may be a single layer structure configured as Cu.

In addition, the bonding pad 108 may be a stack structure configured as Au—Sn, instead of Cu—Sn, or a single layer structure configured as Au, instead of Cu.

Since the bonding pad 108 disposed on the substrate 100 contacts with the connection pad 132 disposed on the printed circuit board, only one Sn layer of the printed circuit board 140 or the substrate 100 may be included.

FIG. 6 is a cross-sectional view showing a module in which a wafer level package according to an embodiment of the present invention is installed in a module printed circuit board 160.

As shown in FIG. 6, a module may be manufactured by disposing a wafer level package attached with a printed circuit board 140 on another module printed circuit board 160 and covering the wafer level package with an insulation wrapping member 150. Particularly, a memory module printed circuit board is a printed circuit board modularized after installing a plurality of memory semiconductor device packages on the surface and may expand DRAM capacity within a PC or a server according to application fields.

The memory module printed circuit board performs a function of expanding memory capacity or data input and output.

Manufacturing cost can be reduced by simplifying the process through the wafer level package and the manufacturing method thereof according to the present invention.

In addition, since the wafer level package according to the present invention is hermetically sealed by metal bonding, reliability can be improved.

Although the present invention has been described above, those skilled in the art may recognize that the present invention may be implemented in other forms while maintaining the technical spirit and essential features of the present invention.

Although the scope of the present invention will be defined by the claims, it is to be interpreted that the configurations directly derived from the claims and all the changes or modified forms derived from the equivalent configurations thereof also fall within the scope of the present invention.

What is claimed is:

1. A wafer level package comprising:
a substrate having a circuit pattern unit, a pad formed to be spaced apart from the circuit pattern unit, a bonding pad disposed on a side of the pad, and a first protection dam; and
a printed circuit board having a connection pad and a second protection dam,
wherein the substrate and the printed circuit board are attached through the bonding pad, the connection pad, the first protection dam and the second protection dam.

2. The package according to claim 1, wherein the bonding pad is configured of conductive materials of single layer or multiple layers.

3. The package according to claim 1, wherein the first protection dam has conductive materials and a structure the same as those of the bonding pad.

4. The package according to claim 1, wherein the bonding pad and the connection pad, and the first protection dam and the second protection dam are attached to configure a Cu—Sn—Cu or Au—Sn—Au structure overall.

5. The package according to claim 4, wherein when the bonding pad and the connection pad, and the first protection dam and the second protection dam are attached to configure a Cu—Sn—Cu structure overall, the connection pad and the second protection dam are configured as a Cu single layer structure if the bonding pad and the first protection dam are a Cu—Sn stack structure, and the connection pad and the second protection dam are configured as a Sn—Cu stack structure if the bonding pad and the first protection dam are a Cu single layer structure.

6. The package according to claim 4, wherein when the bonding pad and the connection pad, and the first protection dam and the second protection dam are attached to configure an Au—Sn—Au structure overall, the connection pad and the second protection dam are configured as an Au single layer structure if the bonding pad and the first protection dam are an Au—Sn stack structure, and the connection pad and the second protection dam are configured as an Sn—Au stack structure if the bonding pad and the first protection dam are an Au single layer structure.

7. The package according to claim 1, wherein the circuit pattern unit is an IDT electrode unit.

8. A method of manufacturing a wafer level package, the method comprising the steps of:
forming a circuit pattern unit on a substrate;
disposing a pad to be spaced apart from the circuit pattern unit;
forming a secondary film on a side of the pad;
forming a protection film, excluding some of the pads on which the secondary film is formed;
disposing a bonding pad and a protection dam on a side of the pad; and
attaching the manufactured substrate and printed circuit board to each other,
wherein the substrate is simply manufactured compared with a plating method.

9. The method according to claim 8, wherein the bonding pad is configured of conductive materials of single layer or multiple layers.

10. The method according to claim 8, wherein the first protection dam has conductive materials and a structure the same as those of the bonding pad.

11. The method according to claim 8, wherein at the step of disposing a bonding pad and a protection dam on a side of the pad, the conductive materials configuring the bonding pad and the first protection dam are simultaneously formed through evaporation.
